(19) United States
(12) Patent Application Publication
(10) Pub. No.: US 2024/0250092 A1
(43) Pub. Date: Jul. 25, 2024

(54) MICRO LIGHT-EMITTING DIODE DISPLAY DEVICE

(71) Applicant: AUO Corporation, Hsin-Chu (TW)

(72) Inventors: Chao-Kun HUANG, Hsin-Chu (TW); Kuo-Hsuan Huang, Hsin-Chu (TW); Chieh-Ming Chen, Hsin-Chu (TW); Bo-Ru Jian, Hsin-Chu (TW); Ta-Wen Liao, Hsin-Chu (TW)

(21) Appl. No.: 18/520,600

(22) Filed: Nov. 28, 2023

(30) Foreign Application Priority Data
Jan. 19, 2023 (TW) 112102853

(51) Int. Cl. H01L 27/12; H01L 25/16; H01L 33/36

(52) U.S. Cl. CPC H01L 27/124; H01L 25/167; H01L 33/36; H01L 33/32

(57) ABSTRACT

A micro light-emitting diode display device includes a circuit substrate, a first light-emitting element, a second light-emitting element, a third light-emitting element, and a conductive layer. The first light-emitting element, the second light-emitting element, and the third light-emitting element are disposed on the circuit substrate and have a first electrode and a second electrode, respectively. The first electrode of the first light-emitting element, the first electrode of the second light-emitting element, and the first electrode of the third light-emitting element are electrically connected to the circuit substrate. The second electrode of the first light-emitting element and the second electrode of the second light-emitting element are a continuous semiconductor material layer. The second electrode of the third light-emitting element is separated from the second electrode of the first light-emitting element and the second electrode of the second light-emitting element.

### CROSS-REFERENCE TO RELATED APPLICATION

This application claims priority to Taiwan application Ser. No. 11/210,2853, filed Jan. 19, 2023, which is herein incorporated by reference.

### BACKGROUND

### Technical Field

The present disclosure relates to a micro light-emitting diode display device.

### Description of Related Art

Micro light-emitting diodes (μLEDs) have good stability and long lifespan. Also, micro light-emitting diodes have the advantage of low energy consumption, high resolution, and high color saturation.

However, as the critical dimensions of micro light-emitting diodes reduce, the way of effectively conducting mass transfer has become a bottleneck in increasing productivity. For example, if micro light-emitting diodes are not precisely picked up or not properly placed during mass transfer, the micro light-emitting diodes may tilt or fall over. This may lead to malfunction of the micro light-emitting diodes after connection and encapsulation, thus reducing the production yield of micro light-emitting diode display devices.

Accordingly, how to provide a micro light-emitting diode display device to solve the aforementioned problems becomes an important issue to be solved by those in the industry.

### SUMMARY

An aspect of the disclosure is to provide a micro light-emitting diode display device that may efficiently solve the aforementioned problems.

According to an embodiment of the disclosure, a micro light-emitting diode display device includes a circuit substrate, a first light-emitting element, a second light-emitting element, a third light-emitting element, and a conductive layer. The circuit substrate has a first contact pad, a second contact pad, and a third contact pad. The first light-emitting element is disposed on the circuit substrate and has a first electrode and a second electrode. The first electrode of the first light-emitting element is electrically connected to the first contact pad. The second light-emitting element is disposed on the circuit substrate and has a first electrode and a second electrode. The first electrode of the second light-emitting element is electrically connected to the second contact pad. The second electrode of the first light-emitting element and the second electrode of the second light-emitting element are a continuous semiconductor material layer. The third light-emitting element is disposed on the circuit substrate and has a first electrode and a second electrode. The first electrode of the third light-emitting element is electrically connected to the third contact pad. The second electrode of the third light-emitting element is separated from the second electrode of the first light-emitting element and the second electrode of the second light-emitting element. The conductive layer is electrically connected to the second electrode of the first light-emitting element, the second electrode of the second light-emitting element, and the second electrode of the third light-emitting element.

In an embodiment of the disclosure, the first light-emitting element, the second light-emitting element, and the third light-emitting element have a first semiconductor layer, a second semiconductor layer, and an active layer disposed between the first semiconductor layer and the second semiconductor layer, respectively. The second semiconductor layer of the first light-emitting element and the second semiconductor layer of the second light-emitting element are a continuous semiconductor material layer. The second semiconductor layer of the third light-emitting element is separated from the second semiconductor layer of the first light-emitting element and the second semiconductor layer of the second light-emitting element.

In an embodiment of the disclosure, the first semiconductor layer of the first light-emitting element, the first semiconductor layer of the second light-emitting element, and the first semiconductor layer of the third light-emitting element include one of an n-type semiconductor layer and a p-type semiconductor layer. The second semiconductor layer of the first light-emitting element, the second semiconductor layer of the second light-emitting element, and the second semiconductor layer of the third light-emitting element include the other of the n-type semiconductor layer and the p-type semiconductor layer.

In an embodiment of the disclosure, the micro light-emitting diode display device further includes a contact pad disposed in the circuit substrate. The conductive layer is electrically connected to the contact pad to form an electrical contact.

In an embodiment of the disclosure, the micro light-emitting diode display device further includes a contact pad disposed outside the circuit substrate. The conductive layer is electrically connected to the contact pad to form an electrical contact.

In an embodiment of the disclosure, the micro light-emitting diode display device further includes a planarization layer disposed between the circuit substrate and the conductive layer. The planarization layer laterally surrounds the first light-emitting element, the second light-emitting element, and the third light-emitting element.

In an embodiment of the disclosure, the micro light-emitting diode display device further includes a contact pad disposed in the circuit substrate. The planarization layer has a conductive via. The conductive layer and the contact pad form an electrical contact through the conductive via.

In an embodiment of the disclosure, the micro light-emitting diode display device further includes a contact pad disposed outside the circuit substrate. The conductive layer is electrically connected to the contact pad to form an electrical contact.

In an embodiment of the disclosure, a lateral width of the third light-emitting element is greater than a lateral width of the first light-emitting element. The lateral width of the third light-emitting element is greater than a lateral width of the second light-emitting element.

In an embodiment of the disclosure, the first light-emitting element and the second light-emitting element include indium gallium nitride.

In an embodiment of the disclosure, the third light-emitting element includes aluminum indium gallium phosphide.

According to another embodiment of the disclosure, a micro light-emitting diode display device includes a circuit substrate, a first light-emitting element, a second light-emitting element, a third light-emitting element, a third electrode, and a conductive layer. The circuit substrate has a first contact pad, a second contact pad, and a third contact pad. The first light-emitting element is disposed on the circuit substrate and has a first electrode, a first semiconductor layer disposed on the first electrode, and an active layer disposed on the first semiconductor layer. The first semiconductor layer is electrically connected to the first contact pad through the first electrode. The second light-emitting element is disposed on the circuit substrate and has a second electrode, a second semiconductor layer disposed on the second electrode, and an active layer disposed on the second semiconductor layer. The second semiconductor layer is electrically connected to the second contact pad through the second electrode. The third electrode covers the active layer of the first light-emitting element and the active layer of the second light-emitting element. The third light-emitting element is disposed on the circuit substrate and has a fourth electrode, a third semiconductor layer disposed on the fourth electrode, an active layer disposed on the third semiconductor layer, and a fifth electrode disposed over the active layer of the third light-emitting element. The third semiconductor layer is electrically connected to the third contact pad through the fourth electrode. The fifth electrode is separated from the third electrode. The conductive layer is electrically connected to the third electrode and the fifth electrode.

In an embodiment of the disclosure, the first light-emitting element further includes a fourth semiconductor layer disposed between the active layer of the first light-emitting element and the third electrode. The second light-emitting element further includes a fifth semiconductor layer disposed between the active layer of the second light-emitting element and the third electrode. The third light-emitting element further includes a sixth semiconductor layer disposed between the active layer of the third light-emitting element and the fifth electrode. The fourth semiconductor layer and the fifth semiconductor layer are electrically connected to the conductive layer through the third electrode. The sixth semiconductor layer is electrically connected to the conductive layer through the fifth electrode. The fourth semiconductor layer, the fifth semiconductor layer, and the sixth semiconductor layer are separated from one another.

In an embodiment of the disclosure, the first semiconductor layer, the second semiconductor layer, and the third semiconductor layer include one of an n-type semiconductor layer and a p-type semiconductor layer. The fourth semiconductor layer, the fifth semiconductor layer, and the sixth semiconductor layer include the other of the n-type semiconductor layer and the p-type semiconductor layer.

In an embodiment of the disclosure, the micro light-emitting diode display device further includes a fourth semiconductor layer disposed between the active layer of the first light-emitting element and the third electrode and between the active layer of the second light-emitting element and the third electrode. The third light-emitting element further includes a fifth semiconductor layer disposed between the active layer of the third light-emitting element and the fifth electrode. The fourth semiconductor layer is electrically connected to the conductive layer through the third electrode. The fifth semiconductor layer is electrically connected to the conductive layer through the fifth electrode. The fourth semiconductor layer is separated from the fifth semiconductor layer.

In an embodiment of the disclosure, the first semiconductor layer, the second semiconductor layer, and the third semiconductor layer include one of an n-type semiconductor layer and a p-type semiconductor layer. The fourth semiconductor layer and the fifth semiconductor layer include the other of the n-type semiconductor layer and the p-type semiconductor layer.

In an embodiment of the disclosure, a lateral width of the third light-emitting element is greater than a lateral width of the first light-emitting element. The lateral width of the third light-emitting element is greater than a lateral width of the second light-emitting element.

Accordingly, in some embodiments of the micro light-emitting diode display device of the present disclosure, by forming a continuous semiconductor material layer with an electrode of the first light-emitting element and an electrode of the second light-emitting element, the stability of the light-emitting element structure may be increased, thereby reducing the risk of the light-emitting element peeling off the substrate during mass transfer. Specifically, the first light-emitting element and the second light-emitting element with relatively small critical dimensions contain the same material. During the fabrication, the first light-emitting element and the second light-emitting element are formed simultaneously. At the same time, the electrodes are formed as a continuous semiconductor material layer and connect the first light-emitting element and the second light-emitting element. As such, the formed structure has a larger lateral width and a smaller aspect ratio. Compared with an original light-emitting element with an extremely high aspect ratio alone, the light-emitting elements connected together are less likely to tilt on the substrate after mass transfer. Therefore, bonding failure may be avoided. In addition, the structure formed can reduce the number of mass transfers, thus reducing the cost and time consumed by mass transfers and simplifying the fabrication.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial cross-sectional view of a micro light-emitting diode display device according to an embodiment of the present disclosure;

FIG. 2 is a partial cross-sectional view of a micro light-emitting diode display device according to an embodiment of the present disclosure;

FIG. 3 is a partial cross-sectional view of a micro light-emitting diode display device according to an embodiment of the present disclosure;

FIG. 4 is a partial cross-sectional view of a micro light-emitting diode display device along a line 4 in FIG. 3 according to an embodiment of the present disclosure;

FIG. 5 is a partial cross-sectional view of a micro light-emitting diode display device according to an embodiment of the present disclosure;

FIG. 6 is a partial cross-sectional view of a micro light-emitting diode display device according to an embodiment of the present disclosure;

FIG. 7 is a partial cross-sectional view of a micro light-emitting diode display device along a line 7 in FIG. 6 according to an embodiment of the present disclosure;

FIG. 8 is a partial cross-sectional view of a micro light-emitting diode display device according to another embodiment of the present disclosure;

FIG. 9 is a partial cross-sectional view of a micro light-emitting diode display device according to another embodiment of the present disclosure;

FIG. 10 is a partial cross-sectional view of a micro light-emitting diode display device according to another embodiment of the present disclosure;

FIG. 11 is a partial cross-sectional view of a micro light-emitting diode display device according to another embodiment of the present disclosure;

FIG. 12 is a partial cross-sectional view of a micro light-emitting diode display device according to another embodiment of the present disclosure; and

FIG. 13 is a partial cross-sectional view of a micro light-emitting diode display device along a line 13 in FIG. 12 according to an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In some embodiments of the present disclosure, light-emitting elements such as micro light-emitting diodes (μLEDs) have vertical structures. Aluminum gallium indium phosphide (AlInGaP) is used as the semiconductor layer material of red μLEDs. Indium gallium nitride (InGaN) is used as the semiconductor layer material of blue μLEDs and green μLEDs.

Since AlInGaP is a quaternary alloy and has a longer minority carrier diffusion length and a higher surface recombination velocity than InGaN, the internal quantum efficiency (IQE) of AlInGaP is lower than that of InGaN. This causes the luminous efficiency of AlInGaP to decrease faster than that of InGaN when scaling down. Therefore, to maintain the required luminous efficiency, in some embodiments of the present disclosure, the critical dimensions of red μLEDs are larger than those of blue μLEDs and green μLEDs. This difference is especially embodied in lateral widths of the μLEDs. That is, the aspect ratios of blue μLEDs and green μLEDs are larger than that of red μLEDs. Hence, without additional supports, blue μLEDs and green μLEDs are more likely to tilt or peel off than red μLEDs.

Accordingly, in the display devices provided in some embodiments of the present disclosure, a blue μLED and a green μLED share an electrode and/or a semiconductor layer to overcome the problem caused by their high aspect ratios.

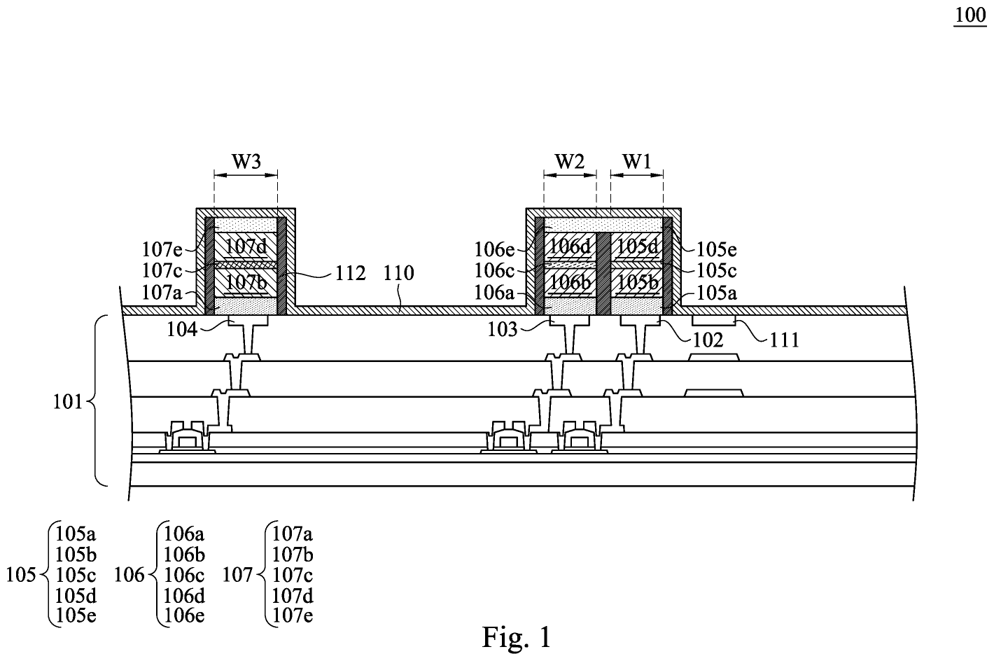

Reference is made to FIG. 1. FIG. 1 is a partial cross-sectional view of a display device 100 according to an embodiment of the present disclosure. As shown in FIG. 1, the display device 100 includes a circuit substrate 101, a first light-emitting element 105, a second light-emitting element 106, a third light-emitting element 107, an insulating layer 112, and a conductive layer 110. The first light-emitting element 105, the second light-emitting element 106, and the third light-emitting element 107 are disposed on the circuit substrate 101.

The circuit substrate 101 has a first contact pad 102, a second contact pad 103, and a third contact pad 104. The first light-emitting element 105 has a first electrode 105a and a second electrode 105e. The first electrode 105a is electrically connected to the first contact pad 102. The second light-emitting element 106 has a first electrode 106a and a second electrode 106e. The first electrode 106a is electrically connected to the second contact pad 103. The second electrode 105e and the second electrode 106e are a continuous semiconductor material layer. In other words, the second electrode 105e and the second electrode 106e are integrally formed into a unitary structure. The third light-emitting element 107 has a first electrode 107a and a second electrode 107e. The first electrode 107a is electrically connected to the third contact pad 104. The second electrode 107e is separated from the second electrode 105e and the second electrode 106e.

As such, through the unitary structure of the second electrode 105e and the second electrode 106e, the first light-emitting element 105 and the second light-emitting element 106 are connected together. Thereby, the aspect ratio of the overall structure is reduced and the overall structure is more firmly supported and better bonded during mass transfer.

In some embodiments, the first light-emitting element 105 and the second light-emitting element 106 are a green μLED and a blue μLED, respectively, while the third light-emitting element 107 is a red μLED. As aforementioned, since the red μLED using AlInGaP has a scaling bottleneck, in some embodiments, a lateral width W3 of the third light-emitting element 107 is larger than a lateral width W1 of the first light-emitting element 105 and a lateral width W2 of the second light-emitting element 106, as shown in FIG. 1.

Regarding the manufacturing process, blue μLEDs and green μLEDs comprising InGaN are simultaneously formed on a semiconductor substrate such as a sapphire substrate. Later, mass transfers of the blue μLEDs and the green μLEDs are performed at the same time. Therefore, the total number of mass transfers can be reduced from three times reduced to twice.

In addition, as critical dimensions of μLEDs shrink, collision and damage to adjacent components, such as other μLEDs or drivers, etc., may occur during repair or replacement processes. Therefore, in the micro light-emitting diode display device of some embodiments of the present disclosure, by connecting blue μLEDs and green μLEDs together, repair and replacement of μLEDs may be more effective.

As shown in FIG. 1, the insulating layer 112 laterally surrounds the first light-emitting element 105, the second light-emitting element 106, and the third light-emitting element 107. The conductive layer 110 is electrically connected to the second electrode 105e, the second electrode 106e, and the second electrode 107e.

As shown in FIG. 1, the first light-emitting element 105 includes a first semiconductor layer 105b, a second semiconductor layer 105d, and an active layer 105c. The active layer 105c is disposed between the first semiconductor layer 105b and the second semiconductor layer 105d. The second light-emitting element 106 includes a first semiconductor layer 106b, a second semiconductor layer 106d, and an active layer 106c. The active layer 106c is disposed between the first semiconductor layer 106b and the second semiconductor layer 106d. The third light-emitting element 107 includes a first semiconductor layer 107b, a second semiconductor layer 107d, and an active layer 107c. The active layer 107c is disposed between the first semiconductor layer 107b and the second semiconductor layer 107d.

In some embodiments, the first semiconductor layer 105b, the first semiconductor layer 106b, and the first semiconductor layer 107b include one of an n-type semiconductor and a p-type semiconductor. The second semiconductor layer 105d, the second semiconductor layer 106d, and the second semiconductor layer 107d include the other of the n-type semiconductors and the p-type semiconductors. For example, when the first semiconductor layer 105b and the first semiconductor layer 106b are p-InGaN and the first semiconductor layer 107b is p-AlInGaP, then the second semiconductor layer 105d and the second semiconductor layer 106d are n-InGaN and the second semiconductor layer 107d is n-AlInGaP.

As shown in FIG. 1, the display device 100 further includes a contact pad 111 disposed in the circuit substrate 101. As aforementioned, the conductive layer 110 is electrically connected to the second electrode 105e, the second electrode 106e, and the second electrode 107e. Also, the conductive layer 110 is electrically connected to the contact pad 111.

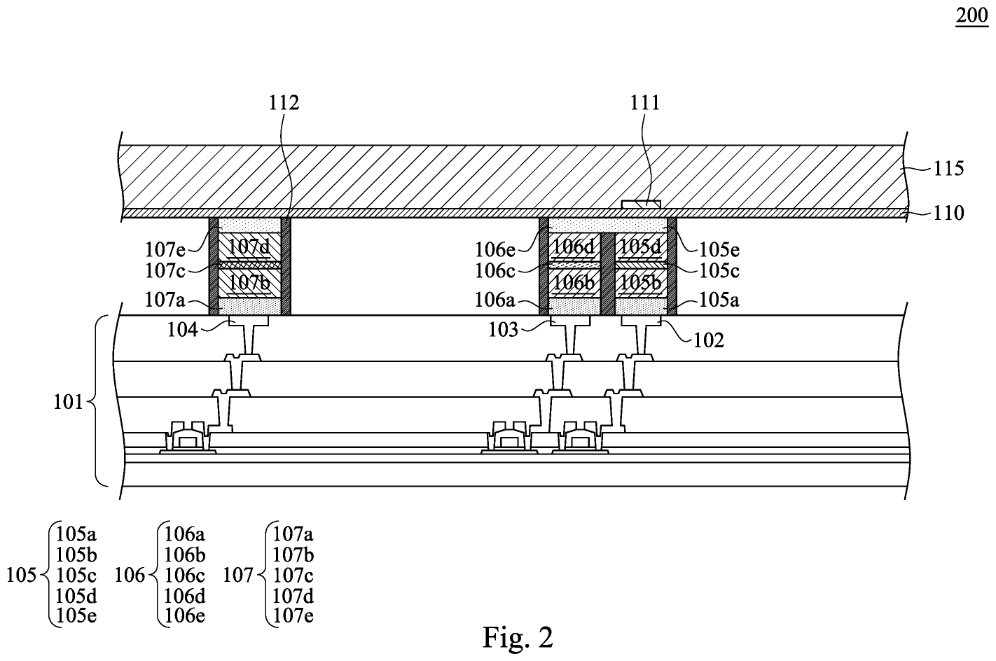

In some embodiments, the contact pads 111 are disposed outside the circuit substrate 101, as shown in FIG. 2. FIG. 2 is a partial cross-sectional view of a display device 200 according to an embodiment of the present disclosure. The display device 200 further includes a subtend substrate 115 in which the contact pad 111 is disposed. Similarly, the conductive layer 110 is electrically connected to the second electrode 105e, the second electrode 106e, and the second electrode 107e. Also, the conductive layer 110 is electrically connected to the contact pad 111 in the subtend substrate 115.

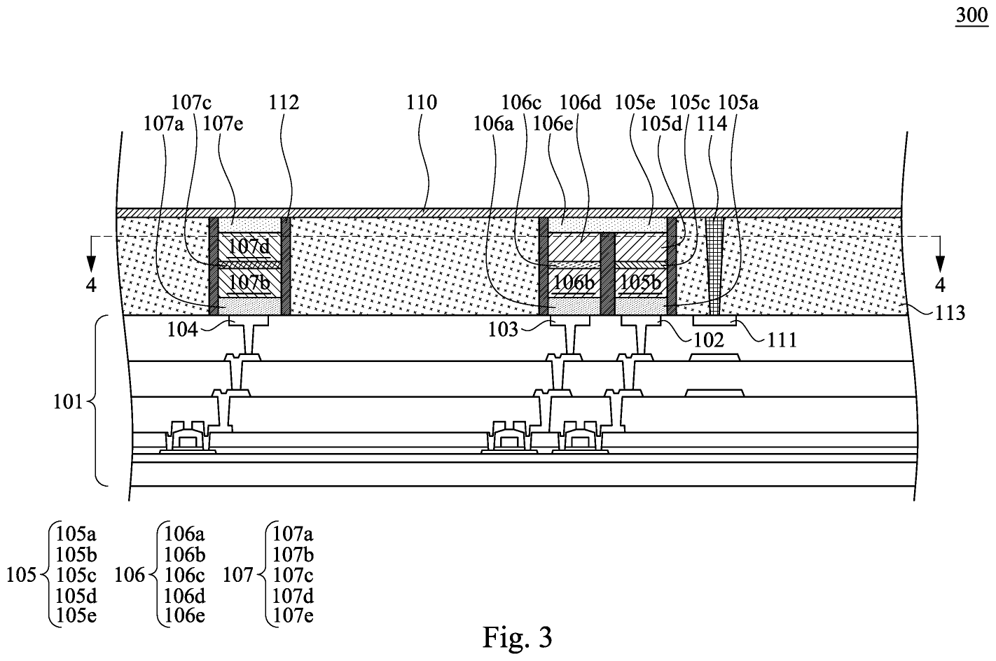

Reference is made to FIG. 3. FIG. 3 is a partial cross-sectional view of a display device 300 according to an embodiment of the present disclosure. The difference between the display device 300 and the display device 100 is that the display device 300 further includes a planarization layer 113. As shown in FIG. 3, the planarization layer 113 is disposed between the circuit substrate 101 and the conductive layer 110. The planarization layer 113 laterally surrounds the first light-emitting element 105, the second light-emitting element 106, and the third light-emitting element 107.

The planarization layer 113 can smooth out of the surface topography across the second electrode 105e, the second electrode 106e, the second electrode 107e, and the circuit substrate 101. This prevents the formed conductive layer 110 from causing faults and damaging the electrical contacts between the conductive layer 110, the second electrodes, and the contact pad 111. In some embodiments, the material of the planarization layer 113 includes ultra-high aperture (UHA) material.

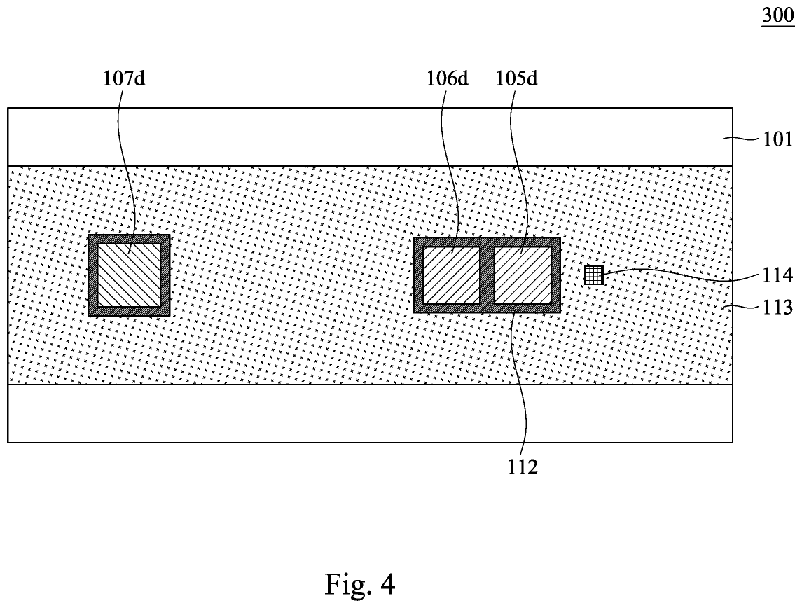

The contact pad 111 of the display device 300 is disposed in the circuit substrate 101. To form an electrical contact between the conductive layer 110 and the contact pads 111 in the circuit substrate 101, the planarization layer 113 has a conductive via 114. The conductive layer 110 and the contact pad 111 form an electrical contact through the conductive via 114, as shown in FIG. 3 and FIG. 4. FIG. 4 is a partial cross-sectional view of the display device 300 along a line 4 in FIG. 3.

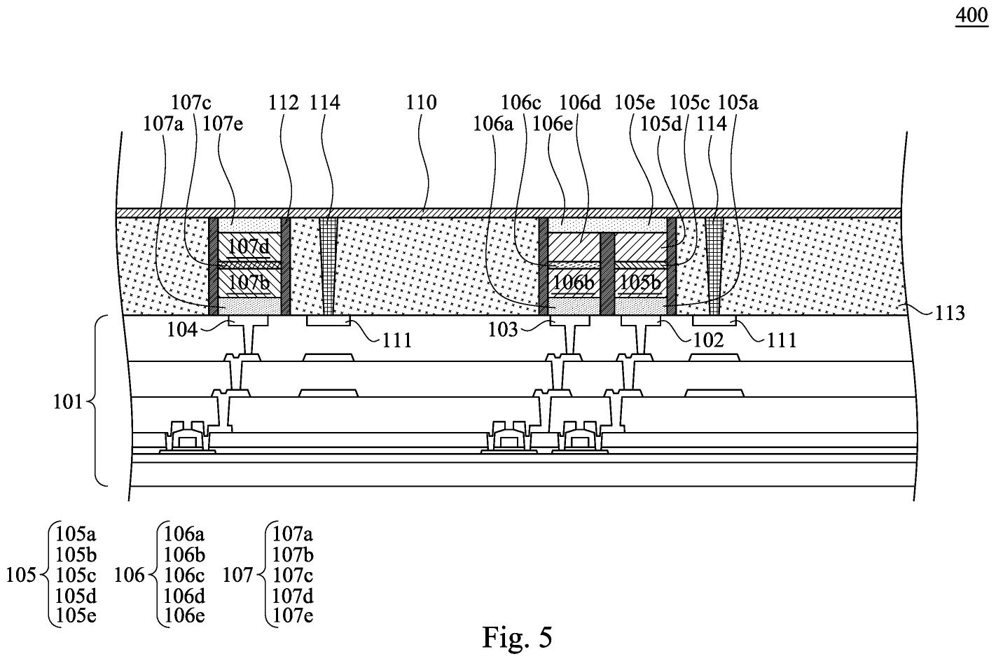

It should be understood that one skilled in the art can include any number of contact pads 111 and a corresponding number of conductive vias 114 as required in the display device within the scope of the present disclosure, as shown in FIG. 5. FIG. 5 is a partial cross-sectional view of a display device 400 according to an embodiment of the present disclosure. The difference between the display device 400 and the display device 300 is that the display device 400 includes two contact pads 111 and two conductive vias 114 in case one of the contact pads 111 or the conductive vias 114 fails.

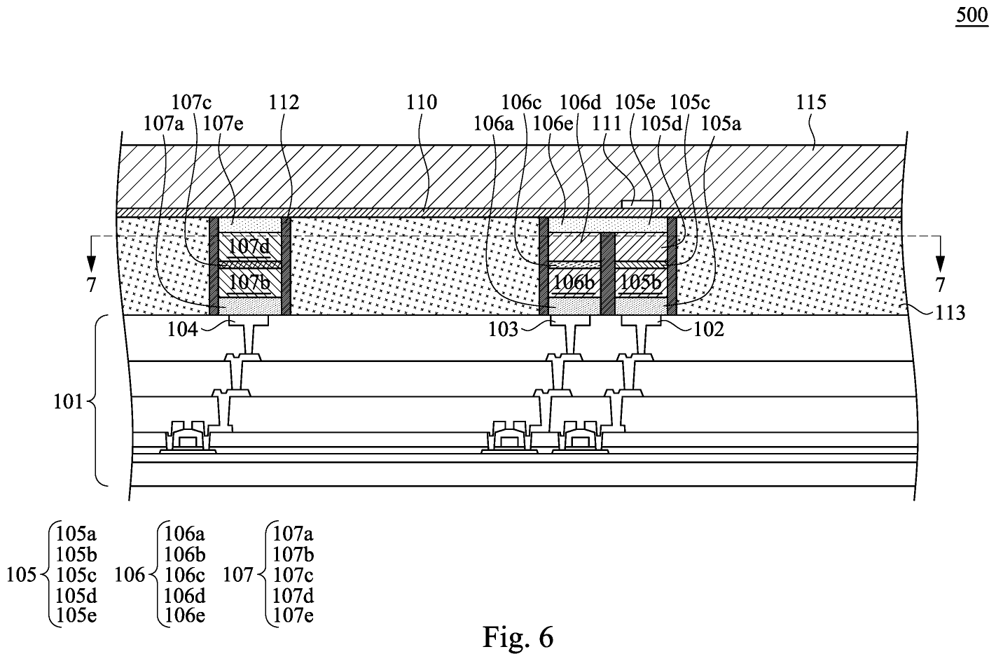

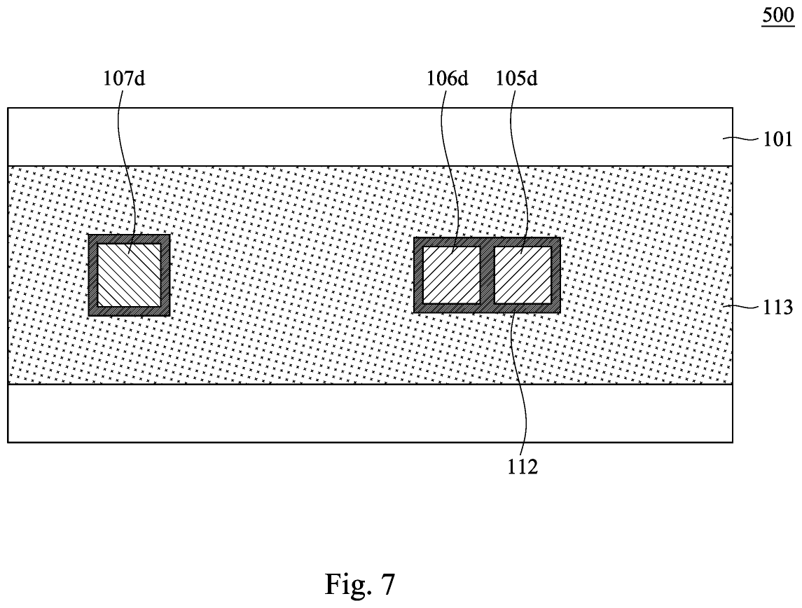

In the embodiments with the planarization layer 113, the contact pads 111 can also be disposed outside the circuit substrate 101, as shown in FIG. 6 and FIG. 7. FIG. 6 is a partial cross-sectional view of a display device 500 according to an embodiment of the present disclosure. FIG. 7 is a partial cross-sectional view of the display device 500 along a line 7 in FIG. 6. The display device 500 further includes a subtend substrate 115 in which the contact pad 111 is disposed. Similarly, the conductive layer 110 is electrically connected to the second electrode 105e, the second electrode 106e, and the second electrode 107e. Also, the conductive layer 110 is electrically connected to the contact pad 111 in the subtend substrate 115.

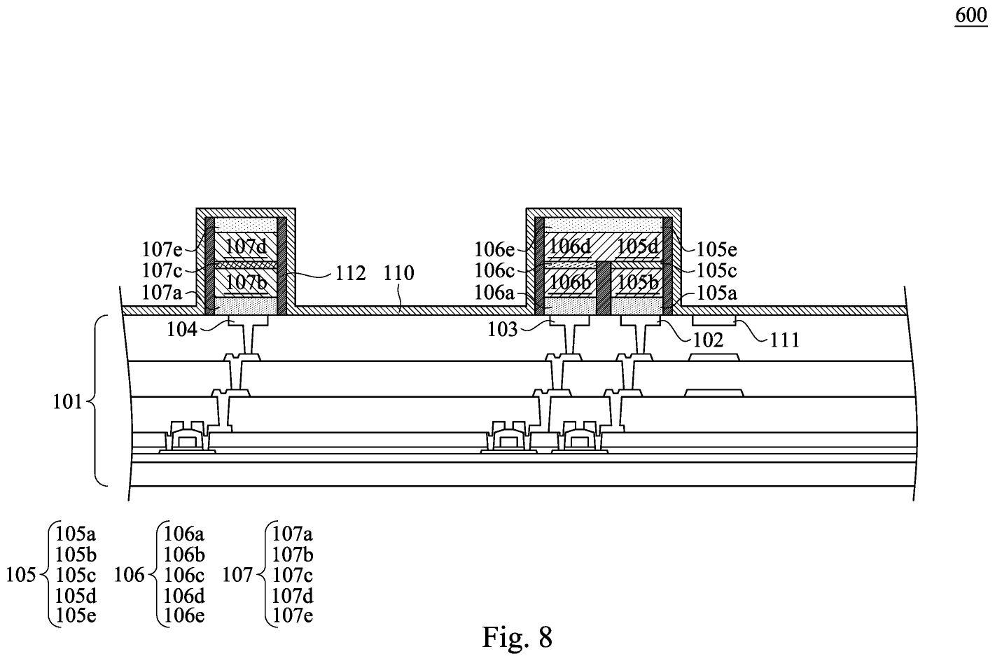

Reference is made to FIG. 8. FIG. 8 is a partial cross-sectional view of a display device 600 according to another embodiment of the present disclosure. As shown in FIG. 8, the display device 600 is similar to the display device 100. However, in the display device 600, the second semiconductor layer 105d and the second semiconductor layer 106d are a continuous semiconductor material layer, such as a continuous layer of InGaN. The second semiconductor layer 107d is separated from the second semiconductor layer 105d and the second semiconductor layer 106d. As such, the stability of the light-emitting element structure can be further increased. Thus, the light-emitting element structure in FIG. 8 is less likely to tilt on the substrate after mass transfer.

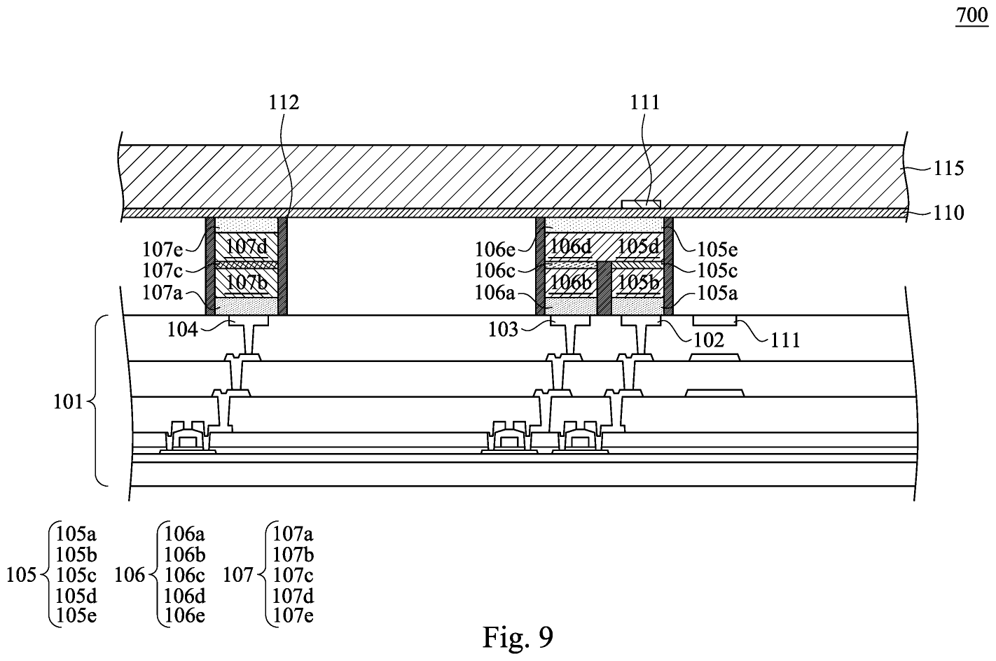

Similarly, reference is made to FIG. 9. FIG. 9 is a partial cross-sectional view of a display device 700 according to another embodiment of the present disclosure. As shown in FIG. 9, the display device 700 is similar to the display device 200. The difference is that in the display device 700, the second semiconductor layer 105d and the second semiconductor layer 106d are a continuous semiconductor material layer.

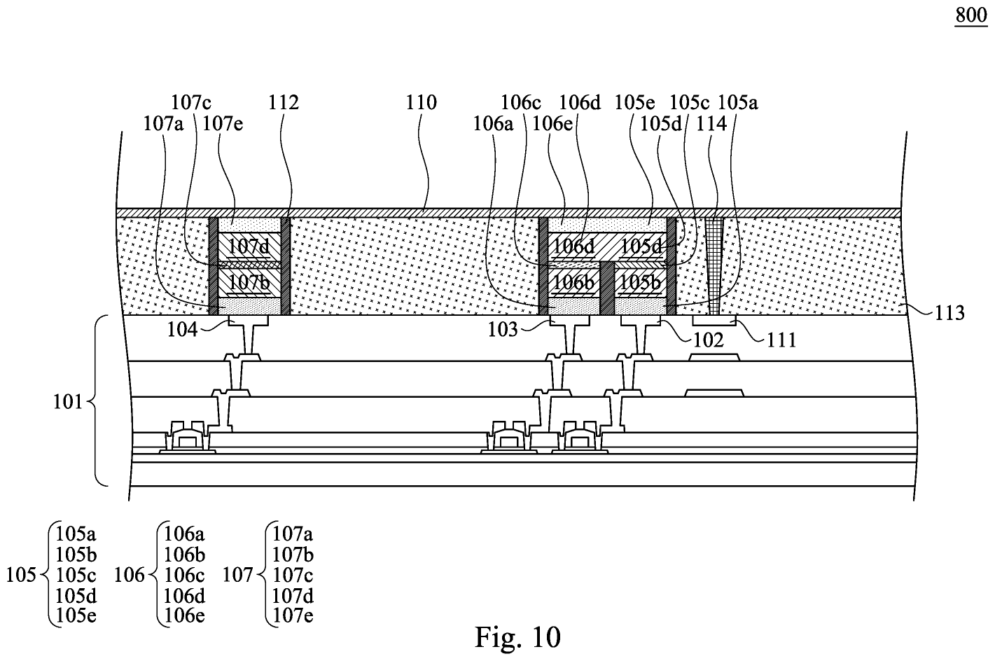

Similarly, reference is made to FIG. 10. FIG. 10 is a partial cross-sectional view of a display device 800 according to another embodiment of the present disclosure. As shown in FIG. 10, the display device 800 is similar to the display device 300. The difference is that in the display device 800, the second semiconductor layer 105d and the second semiconductor layer 106d are a continuous semiconductor material layer.

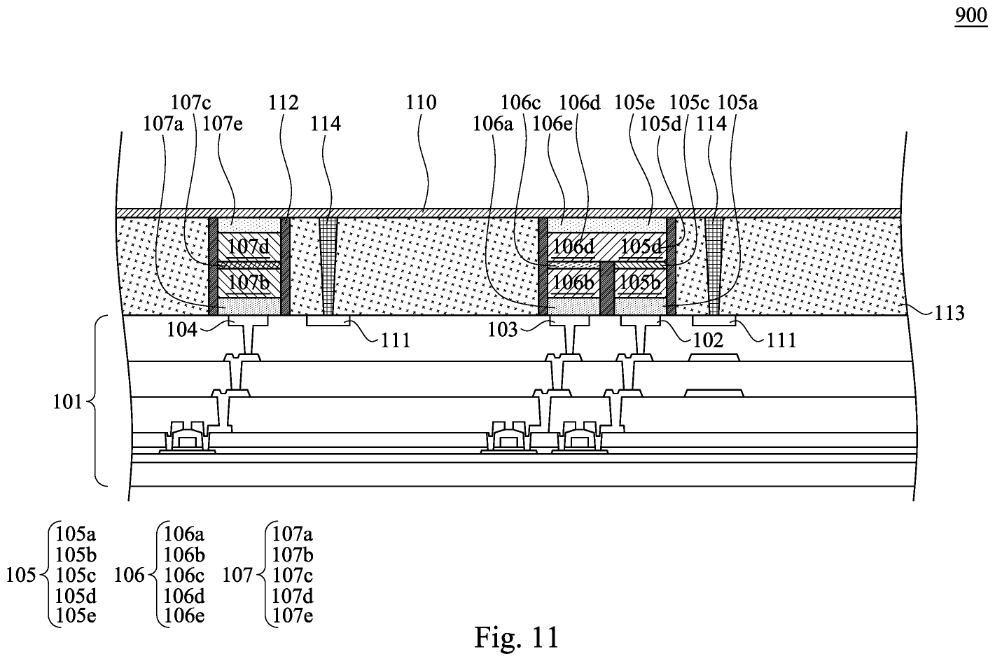

Similarly, reference is made to FIG. 11. FIG. 11 is a partial cross-sectional view of a display device 900 according to another embodiment of the present disclosure. As shown in FIG. 11, the display device 900 is similar to the display device 400. The difference is that in the display device 900, the second semiconductor layer 105d and the second semiconductor layer 106d are a continuous semiconductor material layer.

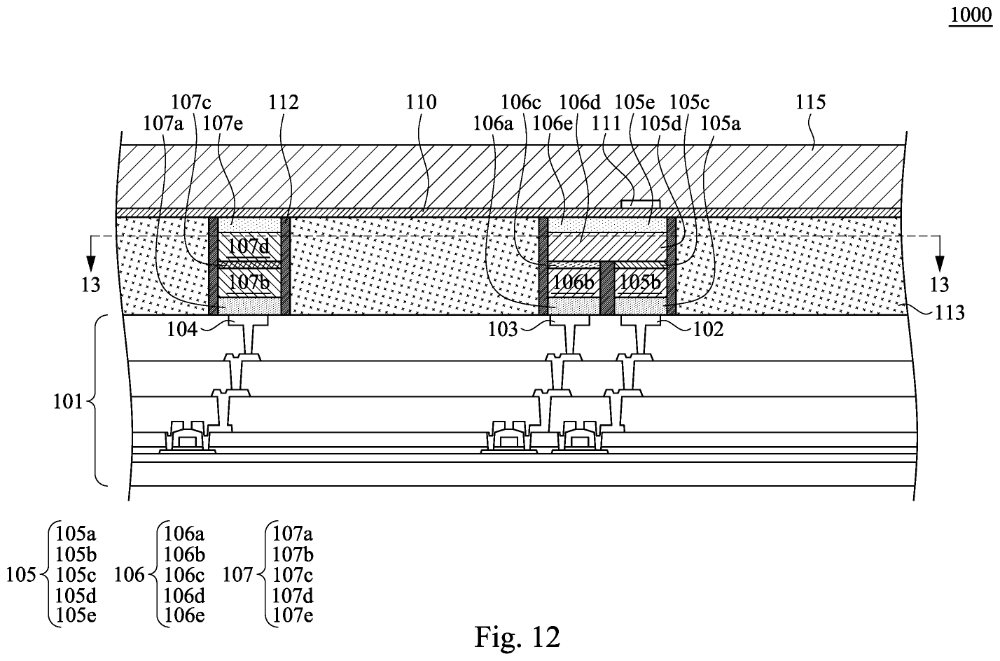

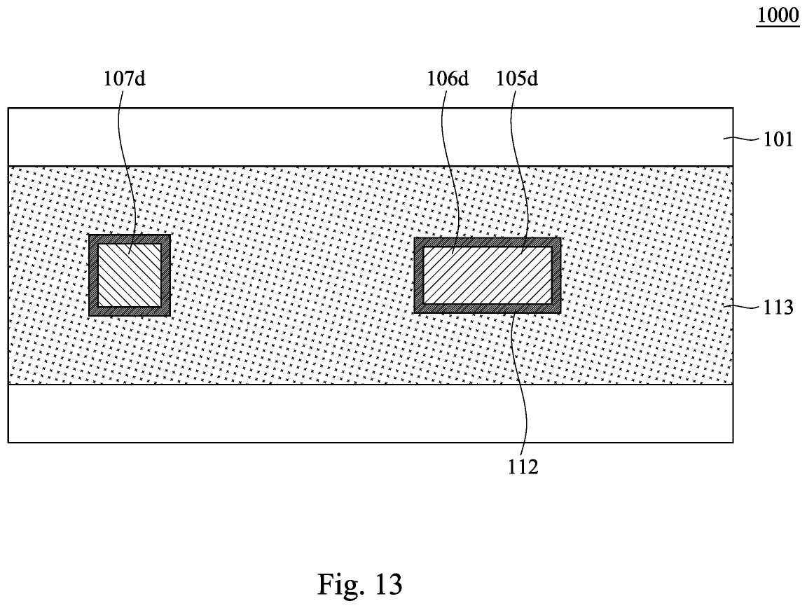

Reference is made to FIG. 12 and FIG. 13. FIG. 12 is a partial cross-sectional view of a display device 1000 according to another embodiment of the present disclosure. FIG. 13 is a partial cross-sectional view of the display device 1000 along a line 13 in FIG. 12. As shown in FIG. 12, the display device 1000 is similar to the display device 500. The difference is that in the display device 1000, the second semiconductor layer 105d and the second semiconductor layer 106d are a continuous semiconductor material layer. Furthermore, as shown in FIG. 13, the second semiconductor layer 105d and the second semiconductor layer 106d are integrally formed into a unitary structure.

According to the foregoing recitations of the embodiments of the disclosure, it may be seen that in some embodiments of the micro light-emitting diode display device of the present disclosure, by forming a continuous semiconductor material layer with an electrode of the first light-emitting element and an electrode of the second light-emitting element, the stability of the light-emitting element structure may be increased, thereby reducing the risk of the light-emitting element peeling off the substrate during mass transfer. Specifically, the first light-emitting element and the second light-emitting element with relatively small critical dimensions contain the same material. During the fabrication, the first light-emitting element and the second light-emitting element are formed simultaneously. At the same time, the electrodes are formed as a continuous semiconductor material layer and connect the first light-emitting element and the second light-emitting element. As such, the formed structure has a larger lateral width and a smaller aspect ratio. Compared with an original light-emitting element with an extremely high aspect ratio alone, the light-emitting elements connected together are less likely to tilt on the substrate after mass transfer. Therefore, bonding failure may be avoided. In addition, the structure formed can reduce the number of mass transfers, thus reducing the cost and time consumed by mass transfers and simplifying the fabrication.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A micro light-emitting diode display device, comprising:
a circuit substrate having a first contact pad, a second contact pad, and a third contact pad;
a first light-emitting element disposed on the circuit substrate and having a first electrode and a second electrode, wherein the first electrode of the first light-emitting element is electrically connected to the first contact pad;
a second light-emitting element disposed on the circuit substrate and having a first electrode and a second electrode, wherein the first electrode of the second light-emitting element is electrically connected to the second contact pad, and the second electrode of the first light-emitting element and the second electrode of the second light-emitting element are a continuous semiconductor material layer;
a third light-emitting element disposed on the circuit substrate and having a first electrode and a second electrode, wherein the first electrode of the third light-emitting element is electrically connected to the third contact pad, and the second electrode of the third light-emitting element is separated from the second electrode of the first light-emitting element and the second electrode of the second light-emitting element; and
a conductive layer electrically connected to the second electrode of the first light-emitting element, the second electrode of the second light-emitting element, and the second electrode of the third light-emitting element.

2. The micro light-emitting diode display device of claim 1, wherein the first light-emitting element, the second light-emitting element, and the third light-emitting element have a first semiconductor layer, a second semiconductor layer, and an active layer disposed between the first semiconductor layer and the second semiconductor layer, respectively, wherein the second semiconductor layer of the first light-emitting element and the second semiconductor layer of the second light-emitting element are a continuous semiconductor material layer, and the second semiconductor layer of the third light-emitting element is separated from the second semiconductor layer of the first light-emitting element and the second semiconductor layer of the second light-emitting element.

3. The micro light-emitting diode display device of claim 2, wherein the first semiconductor layer of the first light-emitting element, the first semiconductor layer of the second light-emitting element, and the first semiconductor layer of the third light-emitting element comprise one of an n-type semiconductor layer and a p-type semiconductor layer, and the second semiconductor layer of the first light-emitting element, the second semiconductor layer of the second light-emitting element, and the second semiconductor layer of the third light-emitting element comprise the other of the n-type semiconductor layer and the p-type semiconductor layer.

4. The micro light-emitting diode display device of claim 1, further comprising a contact pad disposed in the circuit substrate, wherein the conductive layer is electrically connected to the contact pad to form an electrical contact.

5. The micro light-emitting diode display device of claim 1, further comprising a contact pad disposed outside the circuit substrate, wherein the conductive layer is electrically connected to the contact pad to form an electrical contact.

6. The micro light-emitting diode display device of claim 1, further comprising a planarization layer disposed between the circuit substrate and the conductive layer and laterally surrounding the first light-emitting element, the second light-emitting element, and the third light-emitting element.

7. The micro light-emitting diode display device of claim 6, further comprising a contact pad disposed in the circuit substrate, wherein the planarization layer has a conductive via, and the conductive layer and the contact pad form an electrical contact through the conductive via.

8. The micro light-emitting diode display device of claim 6, further comprising a contact pad disposed outside the circuit substrate, wherein the conductive layer is electrically connected to the contact pad to form an electrical contact.

9. The micro light-emitting diode display device of claim 1, wherein a lateral width of the third light-emitting element is greater than a lateral width of the first light-emitting element and the lateral width of the third light-emitting element is greater than a lateral width of the second light-emitting element.

10. The micro light-emitting diode display device of claim 9, wherein the first light-emitting element and the second light-emitting element comprise indium gallium nitride.

11. The micro light-emitting diode display device of claim 9, wherein the third light-emitting element comprises aluminum indium gallium phosphide.

12. A micro light-emitting diode display device, comprising:
a circuit substrate having a first contact pad, a second contact pad, and a third contact pad;
a first light-emitting element disposed on the circuit substrate and having a first electrode, a first semiconductor layer disposed on the first electrode, and an active layer disposed on the first semiconductor layer, wherein the first semiconductor layer is electrically connected to the first contact pad through the first electrode;
a second light-emitting element disposed on the circuit substrate and having a second electrode, a second semiconductor layer disposed on the second electrode, and an active layer disposed on the second semiconductor layer, wherein the second semiconductor layer is electrically connected to the second contact pad through the second electrode;
a third electrode covering the active layer of the first light-emitting element and the active layer of the second light-emitting element;
a third light-emitting element disposed on the circuit substrate and having a fourth electrode, a third semiconductor layer disposed on the fourth electrode, an active layer disposed on the third semiconductor layer, and a fifth electrode disposed over the active layer of the third light-emitting element, wherein the third semiconductor layer is electrically connected to the third contact pad through the fourth electrode and the fifth electrode is separated from the third electrode; and
a conductive layer electrically connected to the third electrode and the fifth electrode.

13. The micro light-emitting diode display device of claim 12, wherein the first light-emitting element further comprises a fourth semiconductor layer disposed between the active layer of the first light-emitting element and the third electrode, the second light-emitting element further comprises a fifth semiconductor layer disposed between the active layer of the second light-emitting element and the third electrode, the third light-emitting element further comprises a sixth semiconductor layer disposed between the active layer of the third light-emitting element and the fifth electrode, wherein the fourth semiconductor layer and the fifth semiconductor layer are electrically connected to the conductive layer through the third electrode, the sixth semiconductor layer is electrically connected to the conductive layer through the fifth electrode, and the fourth semiconductor layer, the fifth semiconductor layer, and the sixth semiconductor layer are separated from one another.

14. The micro light-emitting diode display device of claim 13, wherein the first semiconductor layer, the second semiconductor layer, and the third semiconductor layer comprise one of an n-type semiconductor layer and a p-type semiconductor layer, and the fourth semiconductor layer, the fifth semiconductor layer, and the sixth semiconductor layer comprise the other of the n-type semiconductor layer and the p-type semiconductor layer.

15. The micro light-emitting diode display device of claim 12, further comprising a fourth semiconductor layer disposed between the active layer of the first light-emitting element and the third electrode and between the active layer of the second light-emitting element and the third electrode, the third light-emitting element further comprises a fifth semiconductor layer disposed between the active layer of the third light-emitting element and the fifth electrode, wherein the fourth semiconductor layer is electrically connected to the conductive layer through the third electrode, the fifth semiconductor layer is electrically connected to the conductive layer through the fifth electrode, and the fourth semiconductor layer is separated from the fifth semiconductor layer.

16. The micro light-emitting diode display device of claim 15, wherein the first semiconductor layer, the second semiconductor layer, and the third semiconductor layer comprise one of an n-type semiconductor layer and a p-type semiconductor layer, and the fourth semiconductor layer and the fifth semiconductor layer comprise the other of the n-type semiconductor layer and the p-type semiconductor layer.

17. The micro light-emitting diode display device of claim 12, wherein a lateral width of the third light-emitting element is greater than a lateral width of the first light-emitting element and the lateral width of the third light-emitting element is greater than a lateral width of the second light-emitting element.
